(19) United States
(12) Patent Application Publication
(10) Pub. No.: US 2002/0089322 A1
(43) Pub. Date: Jul. 11, 2002

(54) Modular high parallelism interface for integrated circuit testing, method of assembly, and use of same

(76) Inventors: James Warren Frame, Chicago, IL (US); Mark R. Jones, Mundelein, IL (US)

Correspondence Address: STAAS & HALSEY LLP, 700 Eleventh Street, N.W., Suite 500, Washington, DC, 20001, US

(21) Appl. No.: 09/757,526

(22) Filed: Jan. 11, 2001

(51) Int. Cl. G01R 1/00

(52) U.S. Cl. 324/158.1

(57) ABSTRACT

A high density connector that connects devices under test and a test head that includes coaxial cable connectors on a first end, and connection points located on a male connector portion at a second end, with a waveguide member connecting respective cable connectors and connection points to create a communication pathway having an isolated ground and a 1:1 signal-to-ground ratio. The connector is a PCB, with the waveguides being in a ground-signal-ground configuration with a signal distance between adjacent waveguides being 0.2 inches or less. The coaxial cable connections are modular, allowing cables from the devices under test to be plugged without soldering. This non-solder connection also allows the cables to be unplugged and replugged as necessary. The male connector portion is connected to a female low insertion force connector on the test head in order to complete the connection between the devices under test and the test head.

### BACKGROUND OF THE INVENTION

1. Field of the Invention

This invention relates generally to automatic test equipment used to test integrated circuit elements, and more particularly to interface hardware used in automatic test equipment to connect devices under test to a test head in order to perform the testing.

2. Description of the Related Art

Automatic test equipment (i.e., a tester) is generally used to test semiconductor devices and integrated circuit elements, such as memory or logic for manufacturing defects. A general representation of a tester is shown in FIG. 1. As shown, a tester 1 has a tester body 10 which is in communication with a test head 20. The test head 20 is in communication with devices under test (DUTs) 50 via an interface 30. The DUTs 50 are the various integrated circuit elements 50 being tested. In this way, multiple DUTs 50 can be tested rapidly and simultaneously.

As shown in FIG. 2, the DUTs 50 are arrayed on DUT boards 80. The DUT boards 80, also known as socket boards, device interface boards, and load boards, are held on or in a spacing frame 40. The DUT boards 80 hold the DUTs 50 using spring loaded test sockets (not shown), which make electrical connections between the DUTs 50 and the DUT boards 80.

In order to connect the DUT boards 80 to the test head 20, a mother performance board (MPB) 60 is commonly used. The DUT boards 80 are connected to the MPB 60 through coaxial cables 70. Generally, the coaxial cables 70 are soldered at one end to DUT boards 80 for respective DUTs 50, and soldered at the other end to the MPB 60. In this way, a connection is made, via the DUT boards 80 and coaxial cables 70, between DUTs 50 and the MPB 60. The MPB 60 is then attached to the test head 20 by male low insertion force connectors 90, which are received into female connector 100.

When a new DUT 50 is to be tested, the new DUT 50 is connected to the test socket, completing the electrical connection between the test head 20 and the new DUT 50. The test is then performed. After completion of the test, the DUT 50 is then removed from the test socket, a new DUT 50 of the same type is installed into the test socket.

If an error is detected and a coaxial cable 70 is to be replaced, the coaxial cable 70 must be removed. To remove the coaxial cable, the interface is partially disassembled to provide access to the coaxial cable 70. The coaxial cable 70 is detached from the DUT board 80 and the MPB 60, and a new coaxial cable 70 is soldered to the DUT board 80 and MPB 60 to renew the connection between the DUT board 80 and the MPB 60.

In order to achieve the efficiencies of scale for mass integrated circuit element testing, hundreds of integrated circuit elements 50 are tested at once. As such, there needs to be large quantities of male low insertion force connectors 90, as well as numerous soldering connections between each of the coaxial cables 70 and the MPB 60. In addition, as the connection density increases, the solder connections to the MPB 60 begin to lift off, which breaks the connections between the tester 1 and individual DUTs 50 and prevents these DUTs 50 from being properly tested.

In addition, while these broken solder connections can be repaired, this repair is time consuming and costly in both down time and in labor. This down time is further exacerbated by the increased density of the connections, which often leads to other solder connections breaking during the repair of broken solder connections.

Existing non-solder connectors, such as those seen in the telecommunication industry, do not have sufficient density and scale required in testers to perform large scale testing of integrated circuit elements. Further, while these connectors can have a 1:1 signal-to-ground ratio, they lack an isolated ground for each signal. The lack of an isolated ground leads to degradation of the signal and the introduction of excess noise. This excess noise causes additional problems in the testing of integrated circuits elements, leading to inaccurate testing results and other similar problems.

It is further known to use spring probes as connectors. Spring probes would afford a modular connection between the cables 70 and the MPB 60, which would prevent the problems caused by the soldered connections outlined above. However, spring probes also have problems in signal degradation due to impedance mismatches. These impedance mismatches occur either at the cable 70-spring probe interface, in the spring probe itself, and/or the spring probe-MPB 60 interface. These mismatches cause similar problems to those presented by the use of connectors not having isolated grounds.

In addition, the spring probe connections pose other problems. For instance, while the force required to make an individual spring probe connection is small, due to the large number of spring probes connections that are required for automated testing equipment (ATE) purposes, the collective connection force would be large. Even if this spring force can be applied, it could cause the MPB to deform. Similarly, in order to make sure that all of the spring probe connections are simultaneously made, the MPB 60 would have to be made highly planar to prevent only some of the spring probes forming a connection. Lastly, the prior art does not reveal a spring probe solution that is scalable to the densities required for large scale automated testing of integrated circuit elements.

Lastly, conventional edge connectors such as those used in the computer industry utilize a board (PCB) as one side of a connector to form an edge card. However, the edge cards used in the computer industry are designed for lower megahertz signals and are inappropriate for higher data rates. Since leading edge testing systems require data rates of up to one gigahertz, these edge cards are not designed to handle the data rates required in large scale automated testing performed by ATE. Further, these edge cards often use a high signal-to-ground ratio, which would lead to the introduction of noise and signal degradation in the testing of integrated circuit elements.

### SUMMARY OF THE INVENTION

It is an object of the invention to provide a connection system between devices under test and a test head that provides a secure modular connection for high data rates without causing a degradation in signal quality.

It is a further object of the invention to provide a high density, scalable connection system between devices under test and a test head.

It is a still further object of the invention to provide a high density connection system with a 1:1 ground-to-signal ratio and where each connection has an isolated ground.

It is a further object of the invention to provide a modular connection system between the devices under test and the test head which allows for individual cables to be unplugged and replugged without soldering.

Additional objects and advantages of the invention will be set forth in part in the description which follows and, in part, will be obvious from the description, or may be learned by practice of the invention.

Accordingly, to achieve these and other objects, an embodiment of the invention uses a high parallelism interface having a board with a first side and a second side, with cable connectors on the first side and connection points on the second side, and communication media, each medium having a signal portion and a ground portion connecting respective cable connectors and connection points forming high density communication pathways, and having an isolated ground and a signal-to-ground ratio of 1:1.

A further embodiment of the invention provides a communication interface, comprising a frame housing discretely pluggable, high density connectors, each connector comprising a first side and a second side, with cable connectors on the first side and connection points on the second side, and communication media, each medium having a signal portion and a ground portion connecting respective cable connectors and connection points forming high density communication pathways, and having an isolated ground and a signal-to-ground ratio of 1:1.

A yet further embodiment of the invention provides a tester to test devices under test, the tester having a test head, and a communication interface allowing communication between the test head and the devices under test, the communication interface having discretely pluggable, high density connectors, each connector comprising a first side and a second side, with cable connectors on the first side and connection points on the second side, and communication media, each medium comprising a signal portion and a ground portion connecting respective cable connectors and connection points forming high density communication pathways, and forming an isolated ground and a signal-to-ground ratio of 1:1.

A still further embodiment of the invention provides a method of connecting devices under test to a test head, the method including connecting first ends of cables to the devices under test, and plugging second ends of the cables to a high density interface forming respective high density communication pathways between the devices under test and the test head, each with an isolated ground and a signal-to-ground ratio of 1:1.

### BRIEF DESCRIPTION OF THE DRAWINGS

These and other objects and advantages of the invention will become apparent and more readily appreciated from the following description of the preferred embodiments, taken in conjunction with the accompanying drawings of which:

FIG. 1 schematically shows a conventional tester including the communication between the test body, the test head, and the devices under test.

FIG. 2 shows a conventional interface between the test head and the devices under test using a mother performance board as the interface.

FIG. 3 shows a high density interface between the devices under test and the test head according to an embodiment of the present invention.

FIG. 4 shows a high density interface using a PCB according to an embodiment of the present invention.

FIG. 5 shows a frame holding numerous high density interfaces of FIG. 4 with the coaxial cable connections facing up according to an embodiment of the present invention.

FIG. 6 shows the connections between the high density interfaces and intermediate and end retaining bars with male connector portions facing up according to an embodiment of the present invention.

FIG. 7 shows an intermediate retainer bar for use in holding the high density interfaces according to an embodiment of the present invention.

FIG. 8 shows a cover plate placed over the frame with the male connector portions protruding according to an embodiment of the present invention.

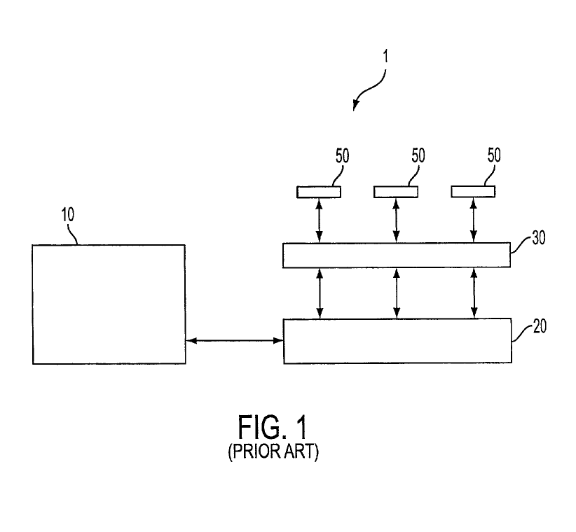

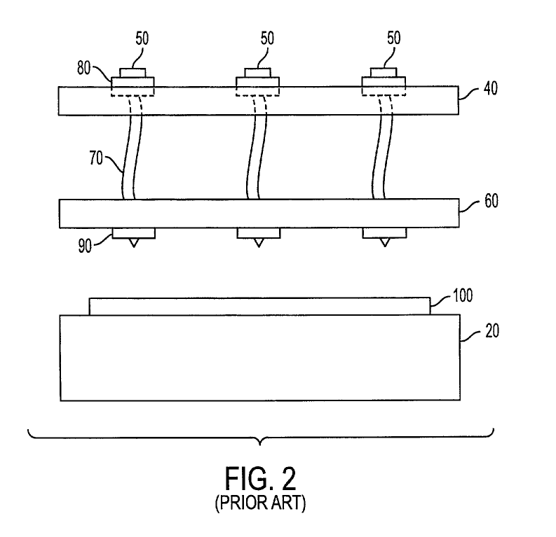

### DESCRIPTION OF THE PREFERRED EMBODIMENTS

Reference will now be made in detail to the present preferred embodiments of the present invention, examples of which are illustrated in the accompanying drawings, wherein like reference numerals refer to the like elements throughout. The embodiments are described below in order to explain the present invention by referring to the figures.

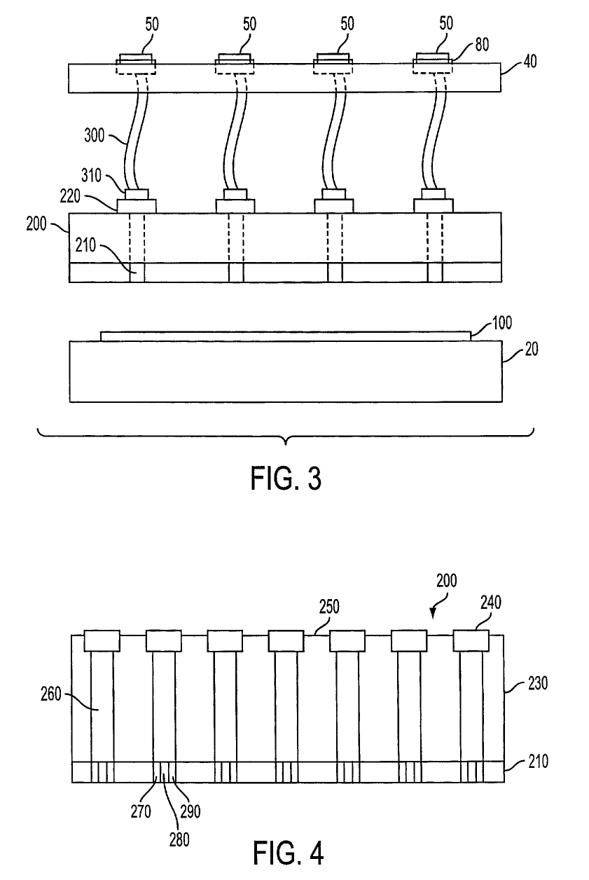

According to an embodiment of the present invention shown in FIGS. 3 and 4, a high density, high parallelism interface connector, which is PCB 200, is connected to the test head 20 using female connector 100. The female connector 100 is a conventional low insertion force connector that receives male connector portion 210 of the PCB 200. The male connector portion 210 has, exposed, the ends of waveguides 260 that form individual communication pathways between the PCB 200 and the test head 20 as will be explained in greater detail below.

The devices under test (DUTs) 50 are conventional DUTs 50, and are connected to coaxial cable 300 via DUT boards 80. The DUT boards 80 are soldered to the respective coaxial cables 300, although it is understood that other forms of modular attachment might also be used. At the other end of each coaxial cable 300, there is a male coaxial connector 310. The male coaxial connector 310 plugs into a respective female coaxial connector 240 on the PCB 200 to form coaxial connection 220. In this way, signals travel along individual pathways between the test head 20 and the DUTs 50 through respective exposed waveguides 260 in the male connector portions 210, waveguides 260, coaxial connection 220, and coaxial cables 300.

The coaxial cables 300 shown are suitable for digital and RF signals, although it is understood that cables used for DC testing could also be provided and realize similar benefits. Further, the connectors 240 and 310 are of the MMCX type, but it is understood that other connectors could be used to form coaxial connection 220 that allow the cables to be plugged and unplugged.

An individual PCB 200 according to an embodiment of the present invention is shown in FIG. 4. The PCB 200 has a PCB body 230. The top of PCB body 230 has female coaxial connectors 240. Each female coaxial connector 240 is attached to the PCB body 230 between prongs 250, which separate the connectors 240. Passing through the PCB body 230 from respective coaxial connectors 240 are waveguides 260. The waveguides 260 terminate at male connector portion 210, where the waveguides 260 are exposed to allow communication between the PCB 200 and the female connector 100.

Each waveguide 260 has a signal 280 between grounds 270 and 290. In this way, signals transmitted through female coaxial cable connector 240 pass through waveguide 260 and continue through male connector portion 210, forming a communication pathway between DUTs 50 and test head 20 that is capable of performing testing of integrated circuit elements. This connection is a high density controlled impedance connection having both communication pathways with an isolated ground, and, due to the ground-signal-ground configuration, a signal-to-ground ratio of 1:1.

The coaxial connections 220 are high density, while still maintaining a one to one (1:1) signal-to-ground ratio and isolated grounds in order to reduce signal noise and improve signal quality. Thus, the distance between grounds 270, 290 is minimized without compromising the signal quality. For the example shown, the distance between signals 280 of adjacent waveguides 260 is 0.2 inches or less. However, it is understood that other ground-to-ground distances may be appropriate based upon the size of the coaxial cable 300, the coaxial cable connector 240, and the size of the waveguide 260.

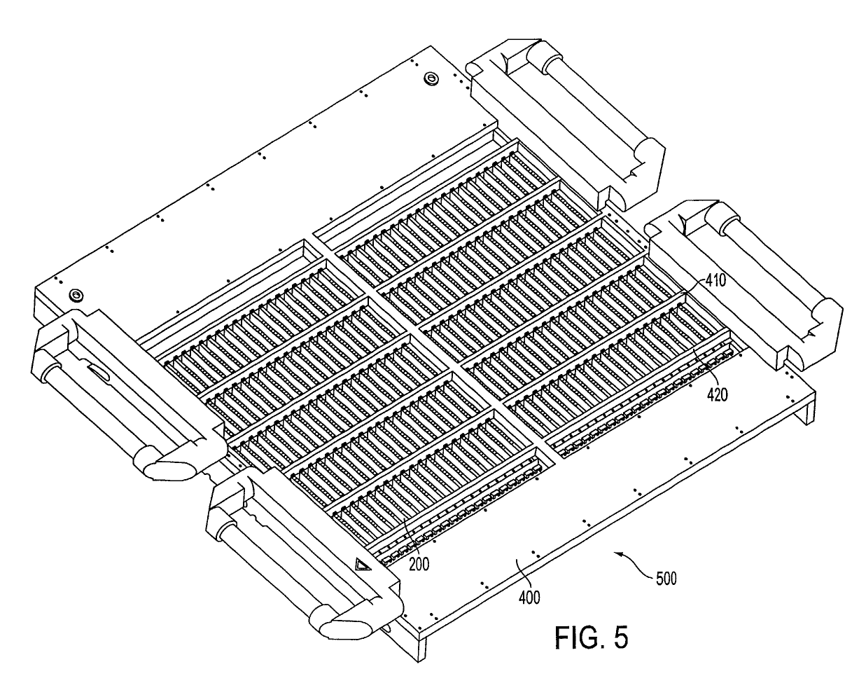

As shown in FIG. 5, in order to utilize numerous PCBs 200, the PCBs 200 are arrayed in a mother performance board (MPB) 500 according to another embodiment of the present invention. The MPB 500 uses a frame 400 to hold the multiple rows of PCBs 200. As shown, the MPB 500 uses PCBs 200 to achieve a capacity of 2900 coaxial connections 220. In the shown example, the frame 400 holds 210 PCBs 200 arrayed in five columns and 42 rows. The frame 400 is configured to allow the removal of individual PCBs 200 in order to allow for repairs and for modifications in the connections 220, and to use more or less PCBs 200 as necessary.

FIGS. 5-8 show the mechanism by which frame 400 holds the PCBs 200 according to an embodiment of the present invention. Frame 400 includes intermediate retainer bars 410 and end retainer bars 420. Intermediate retainer bar 410 and end retainer bar 420 each have multiple slots 440 that hold respective PCBs 200.

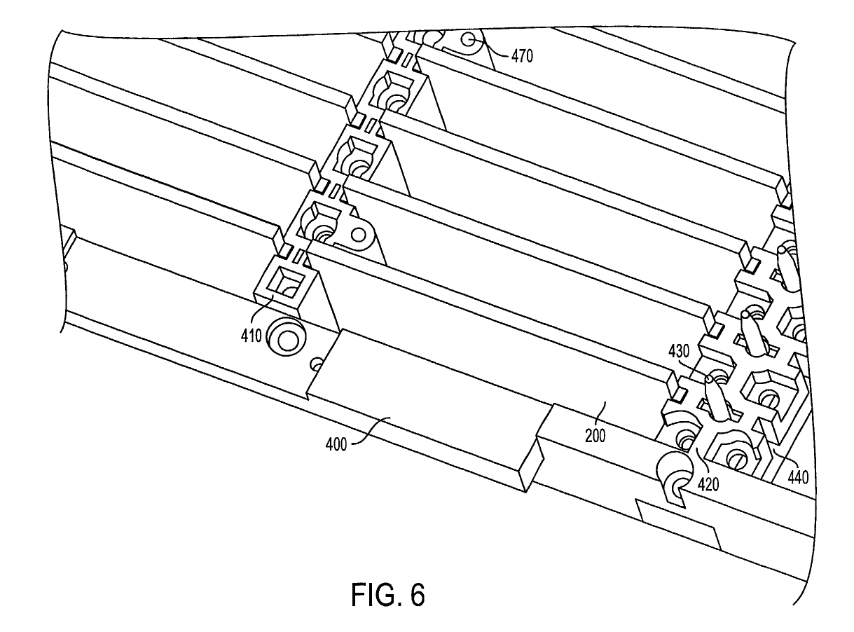

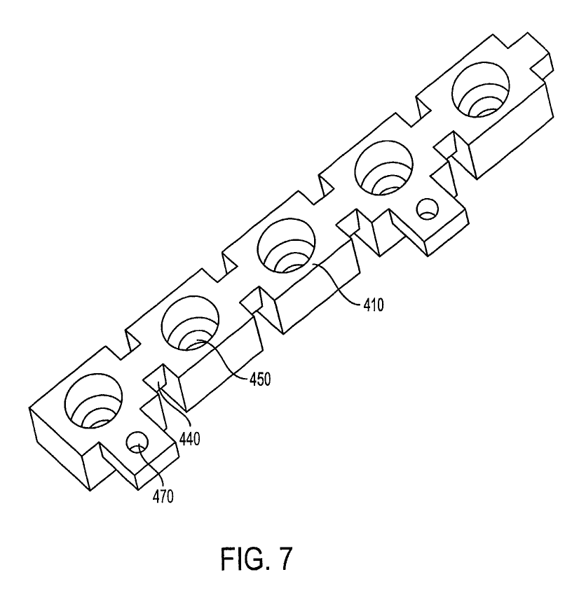

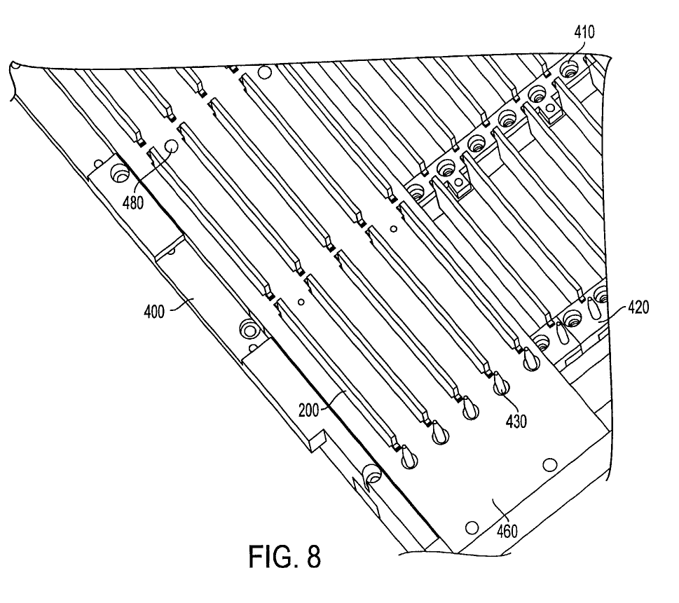

The frame 400 is also modular with retainer bars 410 and 420 being the major components. End retainer bar 420 is designed to be universal, whereas intermediate retainer bar 410 includes a clip hole 470 to one side. The end retainer bar 420 has an alignment hole 450. In order to align and fasten the retainer bars 410, 420, pins 430 are inserted through alignment holes 450 as shown in FIG. 6. Lastly, as shown in FIG. 8, in order to prevent debris and dust from coming into contact with PCBs 200, a dust cover 460 is placed over the frame 400. The cover 460 is aligned using pins 430 and is fastened to the frame 400 using clips 480, which fasten through the cover 460 to clip holes 470 as shown in FIG. 7.

It is understood, but not shown, that the MPB 500 can be non-modular, or can create the same high density controlled impedance capabilities using rectangular or other shaped arrays of high density interface connectors instead of rows of PCBs 200 as shown.

In order to assemble the high density interface according to an embodiment of the present invention, each PCB 200 is prepared with the waveguides 260 and coaxial connectors 240. Next, the PCBs 200 are dropped into frame 400 and secured within using retaining bars 410 and 420. This procedure need only be completed once, due to the modular nature of the PCB 200. The coaxial cables 300 are soldered to the DUT board 80. Next, the cables 300 are pulled through the spacing frame 40 and connected to either an individual PCB 200 or to multiple PCBs 200 using respective cable connectors 240 and 310 to form coaxial connections 220 as shown in FIG. 3. Finally, the individual PCBs 200 are connected to the female connectors 100 on the test head 20 in order to complete the interface between the DUTs 50 and the test head 20.

It is understood that it is possible to attach the cables 300 to the DUT boards 80 without soldering so as to provide a secure transmittal of a signal from the DUT board 80 through the coaxial cable 300.

Generally, for the first assembly of the interface, the interface is only partially assembled so as to allow the cables 300 to be pulled through a spacing frame 40 as is necessary.

Using the above configuration, according to the preferred embodiments of the present invention, it is possible to achieve high density controlled impedance connections between the DUTs and a test head using an improved PCB. The connections have a 1:1 signal-to-ground ratio, with each ground being isolated to reduce and/or eliminate cross talk and other forms of signal degradation. In addition, due to the modular nature of the PCBs and the mother performance board, the interface between the DUTs and test head can be reconfigured by merely replugging cables as is known conventionally. Further, since the cable connections are more securely fastened to the PCB than using conventional solder connections, there is a greatly reduced occurrence of the cable “lifting off” as compared to conventional methods.

Although a few preferred embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A high parallelism interface, comprising:
a board comprising a first side and a second side;
cable connectors on the first side;
connection points on the second side; and
communication media, each medium comprising a signal portion and a ground portion connecting respective cable connectors and connection points forming high density communication pathways, and having an isolated ground and a signal-to-ground ratio of 1:1.

2. The high parallelism interface of claim 1, wherein said cable connectors are coaxial cable connectors.

3. The high parallelism interface of claim 1, wherein said communication media comprise waveguide members.

4. The high parallelism interface of claim 3, wherein the waveguide members are arranged parallel to each other between respective cable connectors and connection points.

5. The high parallelism interface of claim 4, wherein said cable connectors are discretely pluggable.

6. The high parallelism interface of claim 5, wherein the waveguide members communicate digital signals between respective cable connectors and connection points.

7. The high parallelism interface of claim 5, wherein the waveguide members communicate RF signals between respective cable connectors and connection points.

8. The high parallelism interface of claim 5, wherein the waveguide members communicate DC signals between respective cable connectors and connection points.

9. The high parallelism interface of claim 5, wherein the first side and the second side are on opposing sides of said board.

10. The high parallelism interface of claim 5, wherein the first side and the second side are on adjacent sides of said board.

11. The high parallelism interface of claim 3, wherein the waveguide members have a ground-signal-ground configuration, where a distance between signals of adjacent waveguide members is 0.2 inches or less.

12. A communication interface, comprising:
a frame; and
discretely pluggable, high density connectors disposed in said frame forming high density communication pathways, each pathway having an isolated ground and a signal-to-ground ratio of 1:1, each said connector comprising a first side and a second side;
cable connectors on the first side;
connection points on the second side, and communication, each medium comprising a signal portion and a ground portion connecting respective cable connectors and connection points.

13. The communication interface of claim 12, wherein said connectors comprise over 2000 cable connectors.

14. The communication interface of claim 12, wherein the cable connectors are arrayed in rows.

15. The communication interface of claim 14, wherein the cable connectors are coaxial cable connectors.

16. The communication interface of claim 15, wherein the communication media comprise waveguide members.

17. The communication interface of claim 16, wherein the waveguide members are arranged parallel to each other between respective cable connectors and connection points.

18. The communication interface of claim 16, wherein the waveguide members have a ground-signal-ground configuration, where a distance between signals of adjacent waveguide members is 0.2 inches or less.

19. A tester to test integrated circuit elements located on devices under test, comprising:
a test head; and
a communication interface allowing communication between said test head and the devices under test, and comprising discretely pluggable, high density connectors forming high density communication pathways, each pathway having an isolated ground and a signal-to-ground ratio of 1:1, each connector comprising
a first side and a second side;
cable connectors on the first side;
connection points on the second side, and
communication media, each medium comprising a signal portion and a ground portion connecting respective cable connectors and communication points.

20. The tester of claim 19, wherein the connectors comprise over 2000 cable connectors.

21. The tester of claim 19, wherein the cable connectors are coaxial cable connectors.

22. The tester of claim 19, wherein the communication media comprise waveguide members arranged roughly parallel to each other between respective cable connectors and connection points.

23. The tester of claim 19, wherein the communication media comprise waveguide members having a ground-signal-ground configuration where a distance between signals of adjacent waveguide members is 0.2 inches or less.

24. The tester of claim 19, wherein said test head further comprises a female connector, and where at least one of the connection points of said communication interface are in contact with the female connector.

25. The tester of claim 24, wherein the female connector comprises a low insertion force female connector.

26. A method of connecting devices under test to a test head, comprising:
connecting first ends of cables to respective devices under test; and
plugging second ends of the cables to a high density interface forming respective high density communication pathways between the devices under test and the test head, each pathway having an isolated ground and a signal-to-ground ratio of 1:1.

27. The method of claim 26, wherein said plugging comprises plugging the second ends of cables into respective discretely pluggable cable connectors.

28. The method of claim 27, wherein said plugging further comprises inserting a male connector on the high density interface into a female connector on the test head in order to form communication pathways from the high density interface to the test head.

29. The method of claim 27, further comprising unplugging a second end of a cable from a respective discretely pluggable cable connector.

30. The method of claim 29, further comprising replugging the unplugged second end of the cable into another respective discretely pluggable cable connector.

31. The method of claim 28, wherein said plugging further comprises partially assembling the high density interface, pulling cables through a spacing frame, and completing the assembly of the high density interface.
